(19) United States
(12) Patent Application Publication
(10) Pub. No.: US 2008/0117603 A1
(43) Pub. Date: May 22, 2008

(54) INSTALLATION MECHANISM

(75) Inventors: Matthew S. Henry, San Diego, CA (US); David J. Jensen, Raleigh, NC (US); Seth D. Lewis, Rochester, MN (US); John F. Nations, Raleigh, NC (US)

Correspondence Address: SAWYER LAW GROUP LLP, PO BOX 51418, PALO ALTO, CA, 94303, US

(73) Assignee: International Business Machines Corporation, Armonk, NY (US)

(21) Appl. No.: 11/560,741

(22) Filed: Nov. 16, 2006

(51) Int. Cl. H05K 7/12; H05K 7/14

(52) U.S. Cl. 361/740

(57) ABSTRACT

An apparatus for installing a module in a computer system. In one embodiment, the apparatus includes a sliding member movably coupled to a base of a module, where the sliding member includes a handle that allows a user to move the sliding member. The apparatus also includes one or more levers movably coupled to the sliding member, where the one or more levers include extension ends operable to secure the module to a chassis. The apparatus remains within the module except for the handle and except for the extension ends when the apparatus is in an installed position and the handle. According to the system and method disclosed herein, the apparatus facilitates installation of the module in a computer system in a space saving manner.

### FIELD OF THE INVENTION

The present invention relates to computer systems, and more particularly to a method and system for installing computer system modules.

### BACKGROUND OF THE INVENTION

Computer systems such as blade servers may include various modules that are mounted in a chassis. Modules may include, for example, switch modules, storage modules, power supply modules, cooling modules, etc. A user typically manually installs a module using a cam lever that is mounted on or near the front face of a module such as blade or direct access storage device (DASD) carrier. The problem with conventional solutions is that they are extremely restrictive in terms of overall module size and space available for a given module. For example, a blade-style cam lever is mounted on the side wall of the module. This forces the overall dimensions of the module to an unacceptable size. A DASD-style cam lever blocks too much of the front face of the module.

Accordingly, what is needed is an improved system and method for installing computer system modules. The present invention addresses such a need.

### SUMMARY OF THE INVENTION

An apparatus is disclosed. In one embodiment, the apparatus includes a sliding member movably coupled to a base of a module, where the sliding member includes a handle that allows a user to move the sliding member. The apparatus also includes one or more levers movably coupled to the sliding member, where the one or more levers include extension ends operable to secure the module to a chassis. The apparatus remains within the module except for the handle and except for the extension ends when the apparatus is in an installed position and the handle.

According to the system and method disclosed herein, the apparatus facilitates installation of the module in a computer system in a space saving manner.

### BRIEF DESCRIPTION OF THE DRAWINGS

FIGS. 1 and 2 are perspective diagrams of an installation mechanism in accordance with one embodiment.

FIG. 3 shows a side view of a module in accordance with one embodiment.

FIG. 4 is a perspective diagram of an installation mechanism 200 in accordance with another embodiment.

FIG. 5 is a perspective diagram of an installation mechanism 300 in accordance with another embodiment.

### DETAILED DESCRIPTION OF THE INVENTION

The present invention relates to computer systems, and more particularly to a system for installing computer system modules. The following description is presented to enable one of ordinary skill in the art to make and use the invention, and is provided in the context of a patent application and its requirements. Various modifications to the preferred embodiment and the generic principles and features described herein will be readily apparent to those skilled in the art. Thus, the present invention is not intended to be limited to the embodiments shown, but is to be accorded the widest scope consistent with the principles and features described herein.

An installation mechanism in accordance with the present invention for installing a module in a computer system is disclosed. The installation mechanism is positioned in a narrow space between the module base and the printed circuit board (PCB) of a computer system module. The installation mechanism includes a sliding member having a handle for a user to push and pull. After the user inserts the module into the chassis of the computer system, the user may push the handle, causing the sliding mechanism to actuate levers that engage the chassis. Before removing the module from the chassis, the user may pull the handle, which causes the levers to disengage the module from the chassis. Because most of the installation mechanism is inside of the module, the installation mechanism facilitates installation of computer system modules in an efficient and space-saving manner. To more particularly describe the features of the present invention, refer now to the following description in conjunction within the accompanying figures.

Although the present invention disclosed herein is described in the context of switch modules, the present invention may apply to other types of modules such a storage modules, power supply modules, cooling modules, etc., and still remain within the spirit and scope of the present invention.

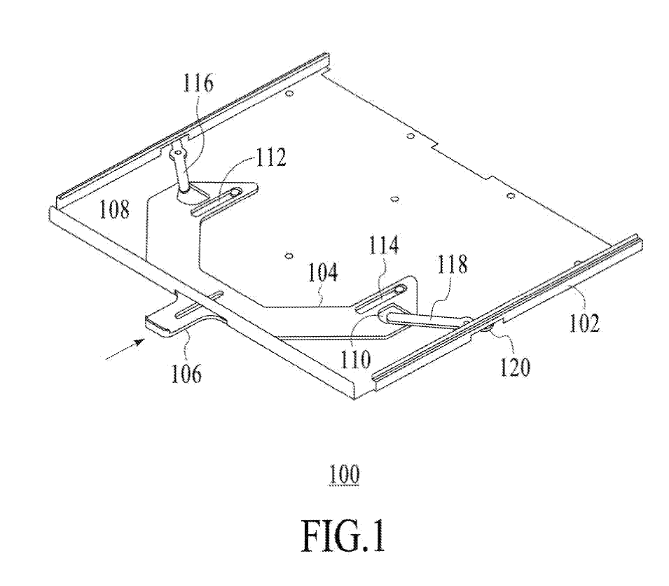

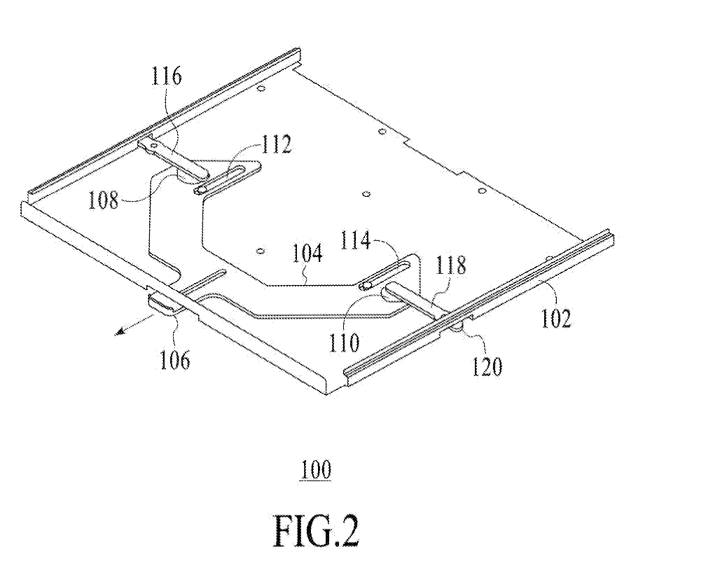

FIGS. 1 and 2 are perspective diagrams of an installation mechanism 100 in accordance with one embodiment. As FIGS. 1 and 2 show, the installation mechanism 100 is movably coupled to a module base 102. The installation mechanism 100 includes a sliding member 104 having a handle 106, notches 108 and 110, and slots 112 and 114. The installation mechanism 100 also includes levers 116 and 118 having extension ends 120 (only one is shown). In one embodiment, the sliding member 104 is positioned between the module base 102 and a printed circuit board (PCB). For ease of illustration, the PCB is now shown in FIGS. 1 and 2, but is shown in FIG. 3.

FIG. 3 shows a side view of a module 122 including a PCB 124 in accordance with one embodiment. As FIG. 3 shows, except for the handle 106 and the extension ends 120, the entire installation mechanism 100 is contained within the narrow space (e.g., ˜2 mm) between the module base 102 and the PCB 124. Reducing the external space required by the installation mechanism frees up the face area of the module 122 thereby enabling stringent thermal and input/output requirements to be more easily met.

Referring again to FIGS. 1 and 2, in operation, the sliding member 104 slides from an extracted position (FIG. 1) to an installed position (FIG. 2). In one embodiment, the sliding member 104 is movably coupled to the module base 102 with any appropriate mechanisms (e.g., nuts or screws) that pass through the slots 110 and 112 and that secure the sliding member 104 to the module base 102 while allowing the sliding member 104 to slide back and forward relative to the module base 102. Similarly, the levers 116 and 118 are movably coupled to the module base 102 with any appropriate mechanisms (e.g., nuts or screws) that secure the levers 116 and 118 to the module base 102, while allowing the levers 116 and 118 to rotate relative to the module base 102.

Upon installation of the module 122 (FIG. 3) into a computer system, a user inserts the module 122 into the chassis of the computer system. Once in place, the user may then push/depress the handle 104 toward the face of the module 122. This causes the sliding member 104 to move from the extracted position (FIG. 1) to the installed position (FIG. 2). As the sliding member 104 moves from the extracted position to the installed position, the sliding member 104 actuates the levers 116 and 118, which are inserted in the notches 108 and 114, respectively. More specifically, as the sliding member 104 pushes the levers 116 and 118, they rotate causing their respective extension ends 120 to extend outside of the perimeter of the module base 102. In one embodiment, the extension ends 120 may have corresponding mating elements (e.g., notches, holes, stops, etc.) in the chassis (not shown) into which the module is inserted upon installation. Accordingly, the extension ends 120 extend away from the module base 122 to engage/mate with their respective mating elements thereby securing the module 122 to the chassis.

To release the module 122 from the chassis, the user pulls the handle 106 away from the module 122. As the sliding member 104 moves from the installed position (FIG. 2) to the extracted position (FIG. 1), the sliding member 104 pulls the levers 116 and 118. This causes them to rotate and retract their respective extension ends 120 into the module 122. By retracting, the extension ends 120 disengage/unmate with their respective mating elements, thereby enabling the module 122 to be freely pulled out of the chassis. Another benefit of the installation mechanism 100 is that the user need only manipulate one touch point, i.e., the handle 106, in order to secure or release the module 122.

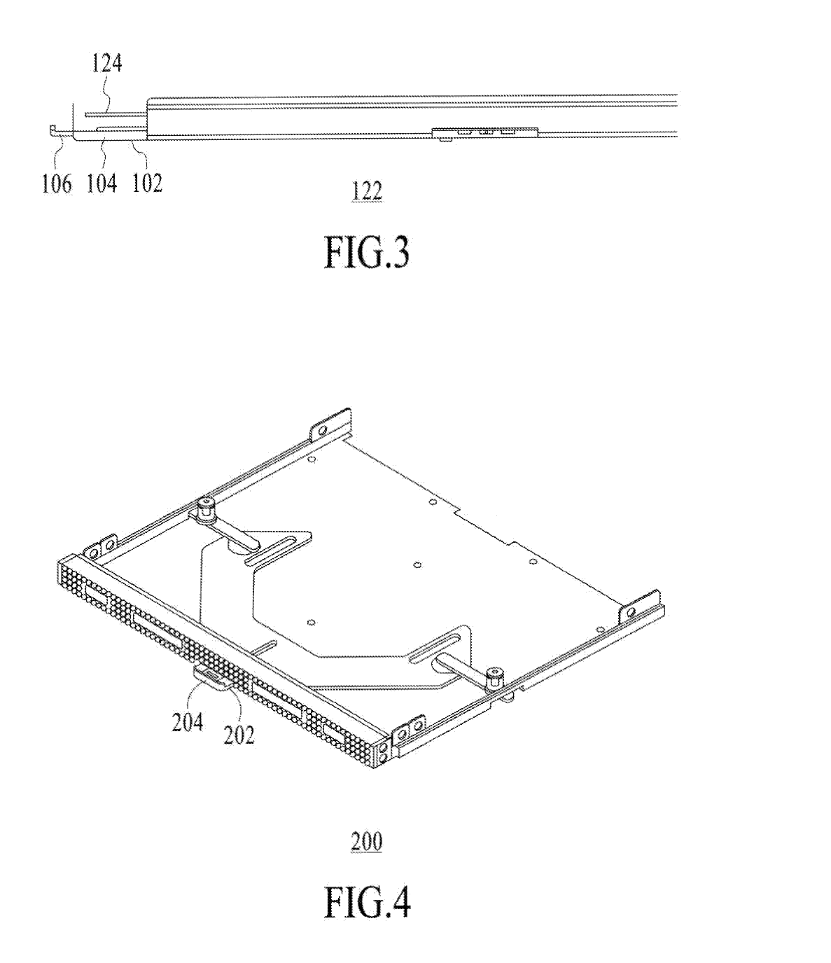

FIG. 4 is a perspective diagram of an installation mechanism 200 in accordance with another embodiment. The installation mechanism 200 of FIG. 4 is similar to that of FIG. 1, except that the handle 202 has an overmold 204 that latches the installation mechanism 200 in the installed position.

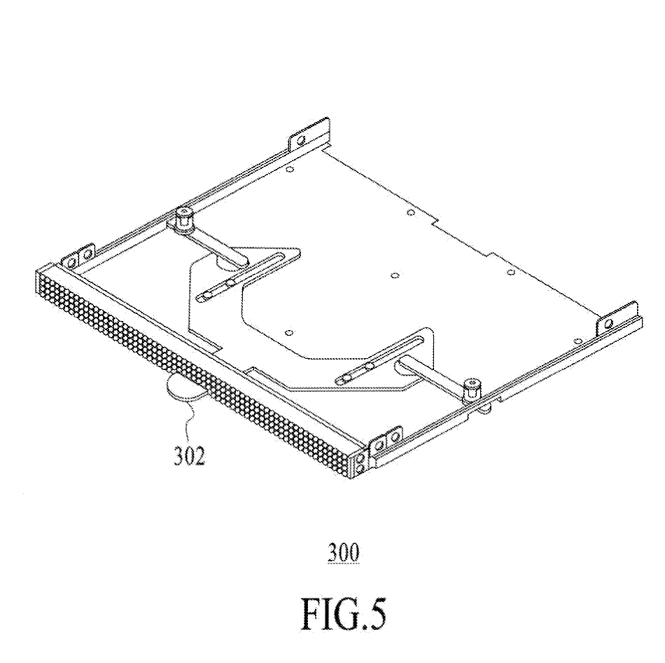

FIG. 5 is a perspective diagram of an installation mechanism 300 in accordance with another embodiment. The installation mechanism 300 of FIG. 5 is similar to that of FIG. 1, except that the handle 302 is shaped as a pull tab to make it easier for a user to manipulate the handle 302.

According to the system disclosed herein, the present invention provides numerous benefits. For example, embodiments of the present invention utilize a minimal front-facing area of the module. Embodiments of the present invention also facilitate meeting stringent thermal and I/O requirements.

An installation mechanism has been disclosed. The installation mechanism is positioned in a narrow space between the module base and the printed circuit board (PCB) of a computer system module. The installation mechanism includes a sliding member having a handle for a user to push and pull. After the user inserts the module into the chassis of the computer system, the user may push the handle to actuate levers that engage the chassis. Before removing the module from the chassis, the user may pull the handle to disengage the module from the chassis.

The present invention has been described in accordance with the embodiments shown. One of ordinary skill in the art will readily recognize that there could be variations to the embodiments, and that any variations would be within the spirit and scope of the present invention. Accordingly, many modifications may be made by one of ordinary skill in the art without departing from the spirit and scope of the appended claims.

What is claimed is:

1. An apparatus comprising:
a sliding member movably coupled to a base of a module, wherein the sliding member comprises a handle that allows a user to move the sliding member; and
one or more levers movably coupled to the sliding member, wherein the one or more levers comprise extension ends operable to secure the module to a chassis, wherein the apparatus remains within the module except for the handle and except for the extension ends when the apparatus is in an installed position and the handle.

2. The apparatus of claim 1 wherein the module comprises a printed circuit board (PCB), and wherein the apparatus is positioned between the base of the module and the PCB.

3. The apparatus of claim 1 wherein the sliding member actuates one or more levers when the sliding member moves from the extracted position to the installed position.

4. The apparatus of claim 1 wherein the extension ends engage the chassis when a user depresses the handle.

5. The apparatus of claim 1 wherein the extension ends disengage the chassis when a user pulls the handle.

6. A system comprising:
a module; and
an apparatus comprising:
a sliding member movably coupled to a base of a module, wherein the sliding member comprises an handle that allows a user to move the sliding member; and
one or more levers movably coupled to the sliding member, wherein the one or more levers comprise extension ends operable to secure the module to a chassis, wherein the apparatus remains within the module except for the handle and except for the extension ends when the apparatus is in an installed position and the handle.

7. The system of claim 6 wherein the module comprises a printed circuit board (PCB), and wherein the apparatus is positioned between the base of the module and the PCB.

8. The system of claim 6 wherein the sliding member actuates one or more levers when the sliding member moves from the extracted position to the installed position.

9. The system of claim 6 wherein the extension ends engage the chassis when a user depresses the handle.

10. The system of claim 6 wherein the extension ends disengage the chassis when a user pulls the handle.

11. The system of claim 6 wherein the system is a blade system.
